(19) United States
(12) Patent Application Publication
(10) Pub. No.: US 2025/0331136 A1
(43) Pub. Date: Oct. 23, 2025

(54) CONTAINER LIQUID-COOLED DATA CENTER

(71) Applicant: Hebei Qinhuai Data Co., Limited., Zhangjiakou City (CN)

(72) Inventor: Binghua ZHANG, Zhangjiakou City (CN)

(21) Appl. No.: 18/939,527

(22) Filed: Nov. 7, 2024

(30) Foreign Application Priority Data
Nov. 28, 2023 (CN) 202311605597.8

(51) Int. Cl. H05K 7/20

(52) U.S. Cl. CPC H05K 7/2079; H05K 7/20272; H05K 7/20609

(57) ABSTRACT

The present disclosure discloses a container liquid-cooled data center, which includes a power transformation and distribution and fire control section, an IT equipment cooling section, and a cooling device section. The IT equipment cooling section includes a plurality of standard container server cluster chassis, each of which is internally provided with an immersion liquid-cooled system connected to the cooling device section through a pipeline. The cooling device section includes a closed cooling tower, an air-cooled heat exchanger, and a cooling water circulation system to dissipate heat from a circulating liquid system.

### CROSS REFERENCE TO RELATED APPLICATION

This application claims priority to Chinese Patent Application No. 202311605597.8, titled “CONTAINER LIQUID-COOLED DATA CENTER” and filed to the China National Intellectual Property Administration on Nov. 28, 2023, the entire contents of which are incorporated herein by reference.

### TECHNICAL FIELD

The present disclosure relates to the field of data center cooling technology, and more particularly, to a container liquid-cooled data center.

### BACKGROUND

Existing servers and data centers use a circulating air cooling method to cool devices such as servers by means of cold air supplied by refrigeration units. With the development of the industry and the increase in power density, cooling capacity of the circulating air cooling method is also approaching its limit, which cannot meet cooling requirements for arrangement of high power density computer rooms.

With the rapid development of cloud computing, demands for server performance is becoming increasingly high. As the server performance improves, power consumption also increases, and cabinet power consumption increases exponentially. In recent years, the power density of cabinets in the data centers has increased by several times.

Therefore, based on the above limitations, it is necessary to provide a new cooling method for cooling server equipment in computer rooms and the data centers that are easy to move and quick to arrange.

### SUMMARY

Embodiments of the present disclosure provide a container liquid-cooled data center to solve problems in the existing data centers using conventional air-cooled mechanical refrigeration, to optimize convenience and reliability of key components of the data center in the present disclosure, to meet requirements of high-power servers in the data centers for heat dissipation and high-density layout, to solve problems of compatibility between server devices and problems in utilizing natural cold sources, to solve problems of excessive energy consumption of cooling devices during operation of the data centers, and to address shortcomings of longer deployment cycle, lower efficiency, and higher costs in conventional computer rooms. The technical solutions are as follows.

In one aspect, there is provided a container liquid-cooled data center, which includes a power transformation and distribution and fire control section, an IT equipment cooling section, and a cooling device section. The power transformation and distribution and fire control section is configured to supply power to the IT equipment cooling section and the cooling device section. The IT equipment cooling section is connected to the cooling device section through a pipeline. The cooling device section is configured to collect heat generated by the IT equipment cooling section and dissipate the heat to outside, thereby forming a cooling cycle.

Further, the IT equipment cooling section includes a plurality of server cluster chassis, and each of the plurality of server cluster chassis is internally provided with a cooling liquid circulation system, which includes a cooling liquid heat exchange distribution unit and a pipeline, where an inlet of the cooling liquid heat exchange distribution unit is communicated with the server cluster chassis through the pipeline, and an outlet of the cooling liquid heat exchange distribution unit is communicated with the cooling device section through the pipeline.

Further, the cooling liquid heat exchange distribution unit includes a cooling liquid heat exchanger, a cooling liquid circulation pump, a cooling liquid supply pipeline, and a cooling liquid return pipeline. An end of the cooling liquid return pipeline is communicated with the server cluster chassis, and other end of the cooling liquid return pipeline is communicated with an inlet of the cooling liquid heat exchanger. An inlet of the cooling liquid circulation pump is communicated with an outlet of the cooling liquid heat exchanger, an outlet of the cooling liquid circulation pump is communicated with an end of the cooling liquid supply pipeline, and other end of the cooling liquid supply pipeline is communicated with the server cluster chassis.

Further, the cooling device section includes a closed cooling tower, an air-cooled heat exchanger, and a cooling water circulation pump. The closed cooling tower is a plate-type cross-flow structure, where a water inlet of the closed cooling tower is communicated with a water outlet of the IT equipment cooling section, and a water outlet of the closed cooling tower is communicated with an inlet of the cooling water circulation pump. A water inlet of the air-cooled heat exchanger is communicated with the water outlet of the IT equipment cooling section, a water outlet of the air-cooled heat exchanger is communicated with the inlet of the cooling water circulation pump, and an outlet of the cooling water circulation pump is communicated with a water inlet of the IT equipment cooling section.

Further, the cooling device section includes at least two cooling water circulation pumps, and both the inlet and the outlet of each of the at least two cooling water circulation pumps are separately connected between the closed cooling tower or air-cooled heat exchanger and the IT equipment cooling section.

Further, the cooling device section also includes a water replenishment apparatus, and the water replenishment apparatus forms a water replenishment cycle together with the cooling water circulation pump.

Further, the cooling liquid is fluorocarbon.

Further, the server cluster chassis adopts a standard container size.

Further, both the IT equipment cooling section and the cooling device section adopt standard container structures.

The technical solutions provided by the embodiments of the present disclosure achieve the following beneficial effects.

In the container liquid-cooled data center provided by the embodiments of the present disclosure, heat dissipation efficiency of servers in a data center computer room is improved on the whole, and a bottleneck problem, for the servers in the data center computer room, of using a mechanical refrigeration system for air cooling is solved. High-power heat dissipation efficiency, high-density layout, and operational reliability of the servers in the data center computer room are increased. A problem of compatibility between the servers in the data center computer room and an immersion cooling liquid is solved. The use of the mechanical refrigeration system for air cooling is saved, and area occupied by the data center is reduced, thus meeting demands for arrangement of more servers. Furthermore, by fully utilizing natural cooling sources, a problem of higher energy consumption for heat dissipation and cooling in the data center computer room is solved. Civil building structures for conventional data center computer rooms are saved, and thus requirements for rapid layout and cost saving are met.

### BRIEF DESCRIPTION OF THE DRAWINGS

To describe the technical solutions in the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic diagram of a container liquid-cooled data center according to an embodiment of the present disclosure;

FIG. 2 is a schematic diagram of a first mode of the container liquid-cooled data center according to an embodiment of the present disclosure;

FIG. 3 is a schematic diagram of a second mode of the container liquid-cooled data center according to an embodiment of the present disclosure;

FIG. 4 is a schematic diagram of a third mode of the container liquid-cooled data center according to an embodiment of the present disclosure;

FIG. 5 is a schematic diagram of a fourth mode of the container liquid-cooled data center according to an embodiment of the present disclosure; and

FIG. 6 is a schematic diagram of system equipment layout of the container liquid-cooled data center according to an embodiment of the present disclosure.

### DETAILED DESCRIPTION

To make the objectives, technical solutions and advantages of the present disclosure clearer, the embodiments of the present disclosure will be further described below in details with reference to the accompanying drawings.

A container liquid-cooled data center provided by the present disclosure includes a power transformation and distribution and fire control section, an IT equipment cooling section, and a cooling device section.

The power transformation and distribution and fire control section includes a BA control cabinet B, a fire control cabinet C, battery cabinets D and E, an HVDC cabinet F, and a power input/output cabinet G. The power transformation and distribution and fire control section is configured to supply power to the IT equipment cooling section and the cooling device section.

The IT equipment cooling section includes a plurality of server cluster chassis 24 and 38, each of which is internally provided with a cooling liquid circulation system. The circulation system includes cooling liquid heat exchange distribution units 23/25 and 35/41, and a pipeline 29/31/36/39. The cooling liquid heat exchange distribution unit includes a cooling liquid heat exchanger 47/51/49/53, a cooling liquid circulation pump 48/52/50/54, a cooling liquid supply pipeline 30/32/37/40, and a cooling liquid return pipeline 29/31/36/39. Two ends of the pipeline 29/31/36/39 are connected to the server cluster chassis and the cooling liquid heat exchange distribution unit, respectively, to form a cooling liquid circulation. The server cluster chassis 24 and 38 are internally provided with servers immersed in a cooling liquid for immersion liquid cooling.

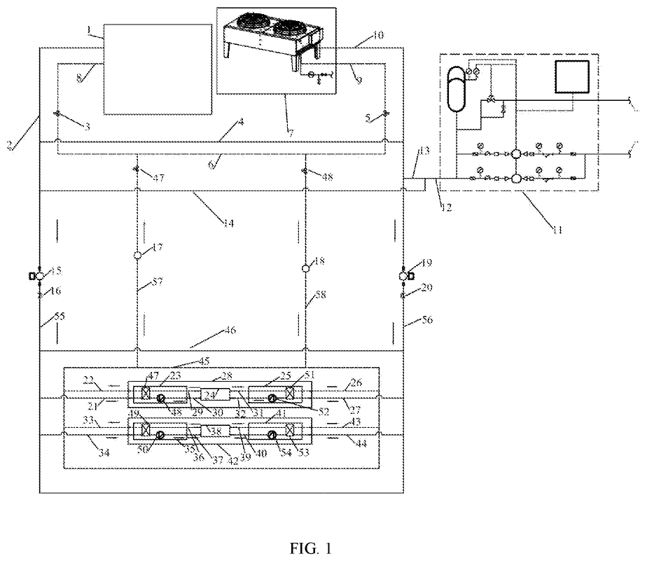

Specifically, referring to FIG. 1, the container liquid-cooled data center includes a closed cooling tower 1, a closed cooling tower outlet pipeline 2, a cooling water inlet electric valve 3, a closed cooling tower inlet pipeline 8, a cooling tower annular pipeline 4, a cooling water inlet electric valve 5, an air-cooled heat exchanger inlet pipeline 9, an air-cooled heat exchanger 7, an air-cooled heat exchanger outlet ring 10, a cooling water circulation pump 15/19, a one-way valve 16/20, a cooling water circulation pump outlet pipeline 55/56, a cooling water supply circulation pipeline 46, a constant pressure water replenishment apparatus 11, a water replenishment pipeline 12/13, a cooling water return pipeline 57/58, a cooling water flow meter 17/18, a cooling water return electric valve 47/48, a cooling water return annular pipeline 45, a cooling liquid heat exchange distribution unit 23/25, 35/41, a cooling water inlet pipeline 21/34/27/44, a cooling liquid heat exchange distribution unit cooling water outlet pipeline 22/33/26/43, a cooling liquid heat exchanger 47/51/49/53, a cooling liquid circulation pump 48/52/50/54, a cooling liquid supply pipeline 30/32/37/40, a cooling liquid return pipeline 29/31/36/39, and a server cluster chassis 24/38, to constitute a cooling circulation system, which is configured to dissipate heat of servers inside the container data center to outside through the closed cooling tower or air-cooled heat exchanger (a server cooling liquid used in this embodiment is a perfluorinated compound, specifically fluorocarbon, which has noninflammability, insulativity, and material compatibility).

The cooling device section includes the closed cooling tower 1, the air-cooled heat exchanger 7, the cooling water circulation pump 15/19, the cooling water pipeline 2/4/6/8/9/10, the cooling water electric valve 3/5, and the constant pressure water replenishment apparatus 11, etc. The closed cooling tower 1 adopts a plate-type cross-flow structure, and allows water to flow in through the pipeline 8 and flow out through the pipeline 2. The air-cooled heat exchanger 7 allows the water to flow in through the pipeline 9 and flow out through the pipeline 10. The cooling water pump 15/19, the electric valve 3/5, and water inlet and outlet pipelines are connected to form a water circulation system. The water replenishment apparatus 11 is connected to the water circulation system to replenish water and pressure.

During operation, the heat inside the server cluster chassis enters the cooling liquid heat exchange distribution unit through the pipeline 29/31/36/39. After the heat is transferred to circulating water in the heat exchanger for heat exchange, the circulating water enters the cooling device section through the water outlet pipeline. Depending on load situations, the circulating water enters the closed cooling tower 1 or the air-cooled heat exchanger 7 for heat exchange and dissipation. The cooled circulating water returns to the IT equipment cooling section to complete the whole cooling cycle.

The closed cooling tower 1 and the air-cooled heat exchanger 7 may also be used in different operating modes to provide cooling capacity to the server cluster chassis 24 and 38. A detailed description is made as follows.

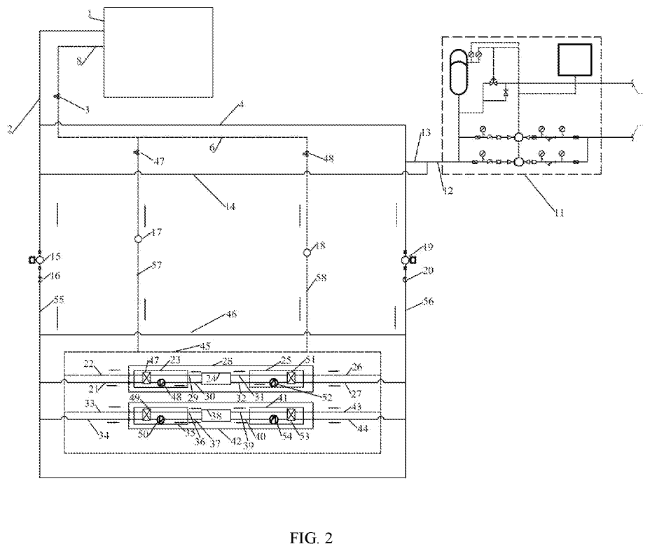

In a first operating mode, referring to FIG. 2, the heat generated in the server cluster chassis 24/38 enters the cooling liquid heat exchanger 47/51/49/53 through the cooling liquid return pipeline 29/31/36/39. After heat exchange is completed in the aforementioned heat exchanger, the circulating water enters the cooling water return annular pipeline through the cooling water outlet pipeline 22/33/26/43 of the cooling liquid heat exchange distribution unit, flows through the cooling water return pipeline 57, the flow meter 17 and the cooling water return electric valve 47, then enters the closed cooling tower annular pipeline 6, then flows through the closed cooling tower electric valve 3 and the closed cooling tower inlet pipeline 8, and enters the closed cooling tower 1 for heat exchange. The cooled circulating water enters the cooling water pump 15 through the closed cooling tower outlet pipeline, and the cooling water pressurized by the cooling water pump enters the cooling water supply circulation pipeline 46 through the one-way valve 16 and the cooling water supply pipeline 55, and then enters the liquid heat exchanger 47/51/49/53 through the cooling water inlet pipeline 21/34/27/44 of the cooling liquid heat exchange distribution unit 23/25 or 35/41. After heat exchange with the cooling liquid is completed, the low-temperature cooling liquid is pressurized by the circulation pumps 48/52 and 50/54 and then is delivered into the server cluster chassis 24 and 38 through the pipelines 30/32 and 37/40, respectively, such that the low-temperature cooling liquid cools down the IT equipment again. In this way, a complete cooling cycle is formed. Based on cooling load inside the server cluster chassis, variable-speed adjustment is made to the cooling liquid circulation pump 48/52 (50/54), the cooling water pump 15 (in this embodiment, the cooling water circulation pump may operate as a single pump or dual pump) and the closed cooling tower 1, to meet requirements for energy-saving operation.

Further, the heat generated in the server cluster chassis 24/38 enters the cooling liquid heat exchanger 47/51/49/53 through the cooling liquid return pipeline 29/31/36/39. After heat exchange is completed in the aforementioned heat exchanger, the circulating water enters the cooling water return annular pipeline through the cooling water outlet pipeline 22/33/26/43 of the cooling liquid heat exchange distribution unit, flows through the cooling water return pipeline 58, the flow meter 18 and the cooling water return electric valve 47, then enters the closed cooling tower annular pipeline 6, then flows through the closed cooling tower electric valve 3 and the closed cooling tower inlet pipeline 8, and enters the closed cooling tower 1 for heat exchange. The cooled circulating water enters the closed cooling tower outlet annular pipeline 4 through the closed cooling tower outlet pipeline, then and enters cooling water pump 19. The cooling water pressurized by the cooling water pump 19 enters the cooling water supply circulation pipeline 46 through the one-way valve 20 and the cooling water supply pipeline 56, and then enters the liquid heat exchanger 47/51/49/53 through the cooling water inlet pipeline 21/34/27/44 of the cooling liquid heat exchange distribution unit 23/25 or 35/41. After heat exchange with the cooling liquid is completed, the low-temperature cooling liquid is pressurized by the circulation pumps 48/52 and 50/54 and then is delivered into the server cluster chassis 24 and 38 through the pipelines 30/32 and 37/40, respectively, such that the low-temperature cooling liquid cools down the IT equipment again. In this way, a complete cooling cycle is formed. Based on the cooling load inside the server cluster chassis, variable-speed adjustment is made to the cooling liquid circulation pump 48/52 (50/54), the cooling water pump 19 (in this embodiment, the cooling water circulation pump may operate as a single pump or dual pump) and the closed cooling tower 1, to meet the requirements for energy-saving operation.

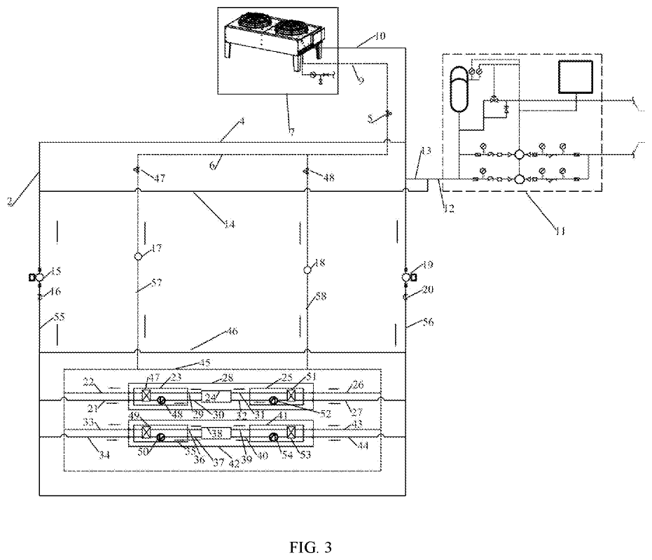

In a second operating mode, referring to FIG. 3, the heat generated in the server cluster chassis 24/38 enters the cooling liquid heat exchanger 47/51/49/53 through the cooling liquid return pipeline 29/31/36/39. After heat exchange is completed in the aforementioned heat exchanger, the circulating water enters the cooling water return annular pipeline through the cooling water outlet pipeline 22/33/26/43 of the cooling liquid heat exchange distribution unit, flows through the cooling water return pipeline 57, the flow meter 17 and the cooling water return electric valve 47, then enters the closed cooling tower annular pipeline 6, then flows through an air-cooled heat exchanger electric valve 5 and an air-cooled heat exchanger inlet pipeline 9, and enters the air-cooled heat exchanger 7 for heat exchange. The cooled circulating water enters the closed cooling tower outlet annular pipeline 4 through the air-cooled heat exchanger outlet pipeline 10, and then enters the cooling water pump 15. The cooling water pressurized by the cooling water pump enters the cooling water supply circulation pipeline 46 through the one-way valve 16 and the cooling water supply pipeline 55, and then enters the liquid heat exchanger 47/51/49/53 through the cooling water inlet pipeline 21/34/27/44 of the cooling liquid heat exchange distribution unit 23/25 or 35/41. After heat exchange with the cooling liquid is completed, the low-temperature cooling liquid is pressurized by the circulation pumps 48/52 and 50/54 and then is delivered into the server cluster chassis 24 and 38 through the pipelines 30/32 and 37/40, respectively, such that the low-temperature cooling liquid cools down the IT equipment again. In this way, a complete cooling cycle is formed. Based on the cooling load inside the server cluster chassis, variable-speed adjustment is made to the cooling liquid circulation pump 48/52 (50/54), the cooling water pump 15 (in this embodiment, the cooling water circulation pump may operate as a single pump or dual pump) and the air-cooled heat exchanger 7, to meet the requirements for energy-saving operation.

Further, the heat generated in the server cluster chassis 24/38 enters the cooling liquid heat exchanger 47/51/49/53 through the cooling liquid return pipeline 29/31/36/39. After heat exchange is completed in the aforementioned heat exchanger, the circulating water enters the cooling water return annular pipeline through the cooling water outlet pipeline 22/33/26/43 of the cooling liquid heat exchange distribution unit, flows through the cooling water return pipeline 58, the flow meter 18 and the cooling water return electric valve 47, then enters the closed cooling tower annular pipeline 6, then flows through the air-cooled heat exchanger electric valve 5 and the air-cooled heat exchanger inlet pipeline 9, and enters the air-cooled heat exchanger 7 for heat exchange. The cooled circulating water enters the cooling water pump 19 through the air-cooled heat exchanger outlet pipeline 10. The cooling water pressurized by the cooling water pump enters the cooling water supply circulation pipeline 46 through the one-way valve 20 and the cooling water supply pipeline 56, and then enters the liquid heat exchanger 47/51/49/53 through the cooling water inlet pipeline 21/34/27/44 of the cooling liquid heat exchange distribution unit 23/25 or 35/41. After heat exchange with the cooling liquid is completed, the low-temperature cooling liquid is pressurized by the circulation pumps 48/52 and 50/54 and then is delivered into the server cluster chassis 24 and 38 through the pipelines 30/32 and 37/40, respectively, such that the low-temperature cooling liquid cools down the IT equipment again. In this way, a complete cooling cycle is formed. Based on the cooling load inside the server cluster chassis, variable-speed adjustment is made to the cooling liquid circulation pump 48/52 (50/54), the cooling water pump 19 (in this embodiment, the cooling water circulation pump may operate as a single pump or dual pump) and the air-cooled heat exchanger 7, to meet the requirements for energy-saving operation.

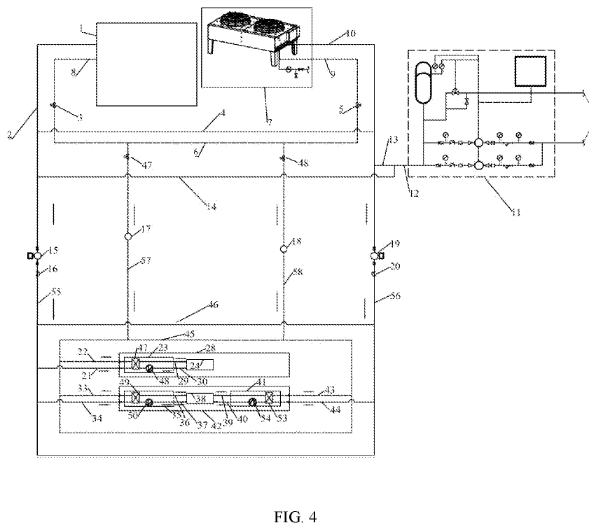

In a third operating mode, referring to FIG. 4, the heat generated in the server cluster chassis 24/38 enters the cooling liquid heat exchanger 47/49/53 through the cooling liquid return pipeline 29/36/39. After heat exchange is completed in the aforementioned heat exchanger, the circulating water enters the cooling water return annular pipeline through the cooling water outlet pipeline 22/33/43 of the cooling liquid heat exchange distribution unit, flows through the cooling water return pipeline 57 (or 58), the flow meter 17 (or 18) and the cooling water return electric valve 47 (or 48), then enters the closed cooling tower annular pipeline 6, then flows through the closed cooling tower electric valve 3 (or the air-cooled heat exchanger electric valve 5) and the closed cooling tower inlet pipeline 8 (or the air-cooled heat exchanger inlet pipeline 9), and enters the closed cooling tower 1 (or the air-cooled heat exchanger 7) for heat exchange. The cooled circulating water enters the cooling water pump 15 (or enters the cooling water pump 19 through the closed cooling tower outlet annular pipeline 4) through the closed cooling tower outlet pipeline 2 (or the air-cooled heat exchanger outlet pipeline 10). The cooling water pressurized by the cooling water pump enters the cooling water supply circulation pipeline 46 through the one-way valve 16 (or 20) and the cooling water supply pipeline 55 (or 56), and then enters the liquid heat exchanger 47/49/53 through the cooling water inlet pipeline 21/34/44 of the cooling liquid heat exchange distribution unit. After heat exchange with the cooling liquid is completed, the low-temperature cooling liquid is pressurized by the circulation pumps 48 and 50/54 and then is delivered into the server cluster chassis 24 and 38 through the pipelines 30 and 37/40, respectively. The low-temperature cooling liquid cools down the IT equipment again. In this way, a complete cooling cycle is formed. Based on the cooling load inside the server cluster chassis, variable-speed adjustment is made to the cooling liquid circulation pump 48 or 50/54, the cooling water pump 15 or 19 (in this embodiment, the cooling water circulation pump may operate as a single pump or dual pump) and the closed cooling tower 1 (or the air-cooled heat exchanger 7), to meet the requirements for energy-saving operation.

In a fourth operating mode, referring to FIG. 5, the heat generated in the server cluster chassis 24/38 enters the cooling liquid heat exchanger 47/51/53 through the cooling liquid return pipeline 29/31/39. After heat exchange is completed in the aforementioned heat exchanger, the circulating water enters the cooling water return annular pipeline through the cooling water outlet pipeline 22/26/43 of the cooling liquid heat exchange distribution unit, flows through the cooling water return pipeline 57 (or 58), the flow meter 17 (or 18) and the cooling water return electric valve 47 (or 48), then enters the closed cooling tower annular pipeline 6, then flows through the closed cooling tower electric valve 3 (or the air-cooled heat exchanger electric valve 5) and the closed cooling tower inlet pipeline 8 (or the air-cooled heat exchanger inlet pipeline 9), and enters the closed cooling tower 1 (or the air-cooled heat exchanger 7) for heat exchange. The cooled circulating water enters the cooling water pump 15 (or enters the cooling water pump 19 through the closed cooling tower outlet annular pipeline 4) through the closed cooling tower outlet pipeline 2 (or the air-cooled heat exchanger outlet pipeline 10). The cooling water pressurized by the cooling water pump enters the cooling water supply circulation pipeline 46 through the one-way valve 16 (or 20) and the cooling water supply pipeline 55 (or 56), and then enters the liquid heat exchanger 47/49/53 through the cooling water inlet pipeline 21/34/44 of the cooling liquid heat exchange distribution unit. After heat exchange with the cooling liquid is completed, the low-temperature cooling liquid is pressurized by the circulation pumps 48 and 50/54 and then is delivered into the server cluster chassis 24 and 38 through the pipelines 30 and 37/40, respectively. The low-temperature cooling liquid cools down the IT equipment again. In this way, a complete cooling cycle is formed. Based on the cooling load inside the server cluster chassis, variable-speed adjustment is made to the cooling liquid circulation pump 48 or 50/54, the cooling water pump 15 or 19 (in this embodiment, the cooling water circulation pump may operate as a single pump or dual pump) and the closed cooling tower 1 (or the air-cooled heat exchanger 7), to meet the requirements for energy-saving operation.

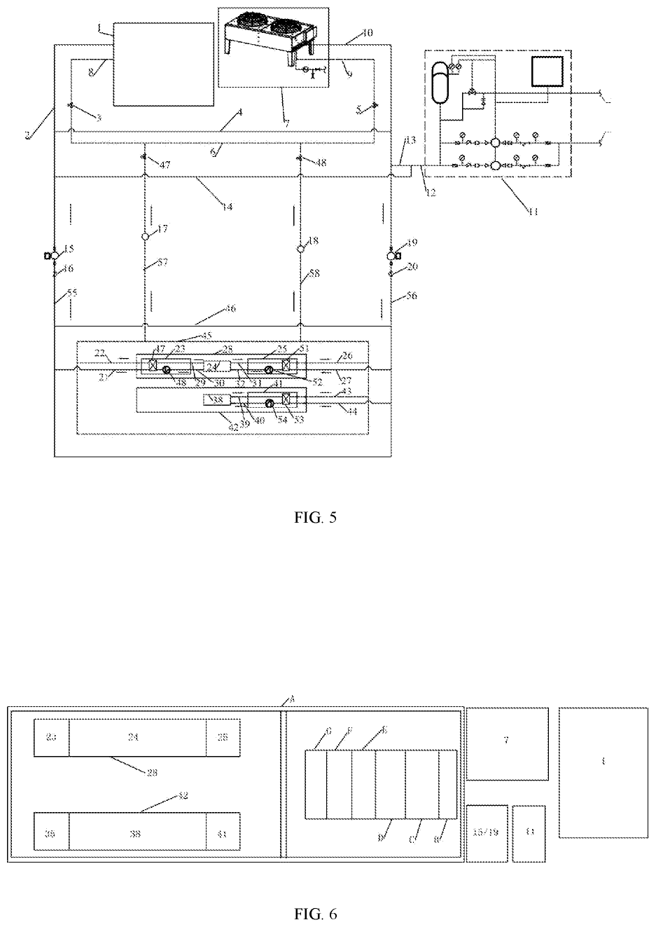

Reference is made to FIG. 6 for system equipment layout: container body A, electric control equipment section: BA control cabinet B, fire control cabinet C, battery cabinets D, E, HVDC cabinet F, and power input/output cabinet G; IT equipment section: a first heat exchange group including a liquid-cooled heat exchange distribution unit 23/25 and a server cluster cabinet 24; and a second heat exchange group 42 including a liquid-cooled heat exchange distribution unit 35/41 and a server cluster cabinet 38. The cooling device section is comprised of the air-cooled heat exchanger 7, the constant pressure water replenishment apparatus 11, the cooling water circulation pumps 15 and 19, and the closed cooling tower 1.

The container liquid-cooled data center provided by the above embodiments eliminates a traditional air-cooled mechanical refrigeration system, ensures reliability and material compatibility of the data room server cooling system, and saves more energy than the traditional air-cooled mechanical refrigeration system. Furthermore, conventional civil building computer rooms are saved, making it quicker, simpler, and more efficient in installation and layout, and thus saving costs.

The above embodiments merely express embodiments of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be merely limited by the appended claims.

What is claimed is:

1. A container liquid-cooled data center, comprising a power transformation and distribution and fire control section, an IT equipment cooling section, and a cooling device section; the power transformation and distribution and fire control section is configured to supply power to the IT equipment cooling section and the cooling device section; the IT equipment cooling section is connected to the cooling device section through a pipeline; and
the cooling device section is configured to collect heat generated by the IT equipment cooling section and dissipate the heat to outside, thereby forming a cooling cycle.

2. The container liquid-cooled data center according to claim 1, wherein the IT equipment cooling section comprises a plurality of server cluster chassis, each of the plurality of server cluster chassis is internally provided with a cooling liquid circulation system comprising a cooling liquid heat exchange distribution unit and a pipeline, an inlet of the cooling liquid heat exchange distribution unit is communicated with the server cluster chassis through the pipeline, and an outlet of the cooling liquid heat exchange distribution unit is communicated with the cooling device section through the pipeline.

3. The container liquid-cooled data center according to claim 2, wherein the cooling liquid heat exchange distribution unit comprises a cooling liquid heat exchanger, a cooling liquid circulation pump, a cooling liquid supply pipeline, and a cooling liquid return pipeline; an end of the cooling liquid return pipeline is communicated with the server cluster chassis, and other end of the cooling liquid return pipeline is communicated with an inlet of the cooling liquid heat exchanger; an inlet of the cooling liquid circulation pump is communicated with an outlet of the cooling liquid heat exchanger, and an outlet of the cooling liquid circulation pump is communicated with an end of the cooling liquid supply pipeline; and other end of the cooling liquid supply pipeline is communicated with the server cluster chassis.

4. The container liquid-cooled data center according to claim 1, wherein the cooling device section comprises a closed cooling tower, an air-cooled heat exchanger, and a cooling water circulation pump; the closed cooling tower is a plate-type cross-flow structure, a water inlet of the closed cooling tower is communicated with a water outlet of the IT equipment cooling section, and a water outlet of the closed cooling tower is communicated with an inlet of the cooling water circulation pump; a water inlet of the air-cooled heat exchanger is communicated with the water outlet of the IT equipment cooling section, and a water outlet of the air-cooled heat exchanger is communicated with the inlet of the cooling water circulation pump; and an outlet of the cooling water circulation pump is communicated with a water inlet of the IT equipment cooling section.

5. The container liquid-cooled data center according to claim 4, wherein the cooling device section comprises at least two cooling water circulation pumps, and the inlet and the outlet of each of the at least two cooling water circulation pumps are separately connected between the closed cooling tower or air-cooled heat exchanger and the IT equipment cooling section.

6. The container liquid-cooled data center according to claim 4, wherein the cooling device section further comprises a water replenishment apparatus, and the water replenishment apparatus forms a water replenishment cycle together with the cooling water circulation pump.

7. The container liquid-cooled data center according to claim 4, wherein the cooling liquid is fluorocarbon.

8. The container liquid-cooled data center according to claim 4, wherein the server cluster chassis adopts a standard container size.

9. The container liquid-cooled data center according to claim 4, wherein both the IT equipment cooling section and the cooling device section adopt standard container structures.
